(19) United States
(12) Patent Application Publication
(10) Pub. No.: US 2022/0261515 A1
(43) Pub. Date: Aug. 18, 2022

(54) ENGINEERING SUPPORT SYSTEM WITH A COGNITIVE ENGINEERING GRAPH

(71) Applicant: Siemens Aktiengesellschaft, Munich (DE)

(72) Inventor: Oswin Noetzelmann, Anaheim Hills, CA (US)

(21) Appl. No.: 17/629,811

(22) PCT Filed: Aug. 30, 2019
(86) PCT No.: PCT/US2019/049014

§ 371 Date: Jan. 25, 2022

(51) Int. Cl. G06F 30/20; G06N 5/02

(52) U.S. Cl. CPC G06F 30/20; G06N 5/022

(57) ABSTRACT

A knowledge graph that contains a domain ontology with associated rules is used to provide engineering support. The domain ontology is linked to an engineering system ontology in the knowledge graph. The ontologies are linked using semantic links. Data from the engineering system is received and modeled in the knowledge graph. The data from the engineering system and the linked ontologies, including the associated rules, are analyzed to provide engineering support. The engineering support may be in the form of annotations in the knowledge graph and direct communication through a messaging service or engineering system integrations.

### FIELD

The following disclosure relates to providing engineering support using a knowledge graph.

### BACKGROUND

Engineering involves the use of scientific principles to solve problems. The field of engineering encompasses a large number of specialty areas, each having a more specific emphasis on particular areas of mathematics, applied science, and types of applications. Engineers may utilize several engineering systems to perform their work. Some of the engineering systems may be tailored to the particular specialized field of engineering in which the engineer is working.

Engineering is usually done within a specific problem domain. In order to be able to design solutions within that domain, engineers often need to acquire enough knowledge about the domain. The more complex the problem, the deeper the required domain knowledge often is. This results in engineers taking a long time to master a domain. Engineers may also sacrifice versatility by being forced to specialize in a particular area. Inexperienced engineers are often required to train under an experienced veteran in their field.

### SUMMARY

By way of introduction, the preferred embodiments described below include methods, systems, instructions, and computer readable media for providing engineering support or assistance using a knowledge graph.

In a first aspect, a method is provided for providing engineering assistance. A processor receives a knowledge graph including an engineering domain ontology for an engineering domain. The engineering domain ontology includes a set of rules. The processor receives an engineering system ontology from one or more engineering systems. The processor updates the knowledge graph to include the engineering system ontology. The processor receives engineering data from a first engineering system of the one or more engineering systems. The engineering data includes one or more specifications of an engineering project, a proposed engineering design, a specific engineering problem, or combinations thereof. The processor generates one or more links in the knowledge graph between the engineering domain ontology, the engineering system ontology, and the engineering data based on the one or more engineering systems, the engineering domain, and the engineering domain ontology. The processor provides engineering assistance for the first engineering system based on the knowledge graph, the one or more links, the engineering data, and the engineering domain.

In a second aspect, a system is provided for providing engineering assistance. An adapter is configured to receive a domain ontology for an engineering domain. The adapter is also configured to translate the domain ontology into a knowledge graph, receive an engineering system ontology from one or more engineering systems, update the knowledge graph to include the engineering system ontology, and receive engineering data from a first engineering system of the one or more engineering systems. The engineering data includes one or more specifications of an engineering project, a proposed engineering design, a specific engineering problem, or combinations thereof. An ontology processor is configured to generate one or more links in the knowledge graph between the domain ontology, the engineering system ontology, and the engineering data based on the one or more engineering systems, the engineering domain, and the domain ontology. The ontology processor is also configured to provide engineering assistance for the first engineering system based on the knowledge graph, the one or more links, the engineering data, and the engineering domain.

In a third aspect, an industry-specific support notification system is provided. An ontology processor is coupled with a memory containing instructions that, when executed, cause the ontology processor to receive a knowledge graph including a first structured model of an industry-specific domain. The first structured model includes a set of rules for the industry-specific domain. The executable instructions cause the ontology processor to receive a second structured model of an industry-specific system from one or more industry-specific systems. The executable instructions cause the ontology processor to generate one or more data associations between the first structured model and the second structured model based on the one or more industry-specific systems, the industry-specific domain, and the first structured model. The executable instructions also cause the ontology processor to receive data from a first industry-specific system of the one or more industry-specific systems and provide an industry-specific support notification for the first industry-specific system based on the received data, the knowledge graph, the one or more data associations, and the industry-specific domain.

Any one or more of the aspects described above may be used alone or in combination. These and other aspects, features and advantages will become apparent from the following detailed description of preferred embodiments, which is to be read in connection with the accompanying drawings. The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

The components and the figures are not necessarily to scale, emphasis instead being placed upon illustrating the principles of the invention. Moreover, in the figures, like reference numerals designate corresponding parts throughout the different views.

FIG. 1 illustrates a flowchart fora method of providing engineering assistance from domain knowledge captured in a knowledge graph;

FIG. 2 illustrates an example flowchart for providing engineering support from domain knowledge captured in a knowledge graph including an engineering domain ontology and an engineering system specific ontology; and

FIG. 3 is a block diagram of one embodiment of a system for providing engineering support using a knowledge graph.

### DETAILED DESCRIPTION OF THE DRAWINGS AND PRESENTLY PREFERRED EMBODIMENTS

Embodiments disclosed herein address challenges associated with the amount of knowledge or experience needed in order to properly perform engineering tasks, such as designing or building machines, structures, and other things, or solving specific engineering problems in specific engineering fields, or domains.

Typically, engineers gather experience over time while working with more experienced peers for potentially a long time before mastering a domain. Sometimes standard literature, books or research papers exist to help an engineer learn the domain faster. In some cases, domain specific engineering solutions may be available from a resource, such as an industry peer or industry literature, for use in a very narrow industry niche having specified parameters. For example, a peer in a civil engineering firm may have designed a solution for a very specific problem relating to a particular structure, such as a necessary road curvature for a designated stretch of roadway in a given town, having very specific parameters, such as the material being used to design the road, the speed limit along the roadway at that stretch of road, and state roadway requirements for the particular state the roadway is in. However, this specific solution is limited to a particular problem (roadway curvature), for a particular structure (road), under particular parameters (material, speed limit, and state regulations), and may not be an appropriate solution to other problems outside of those limits, even if the other problems also relate to roadway curvature issues.

The proposed method introduces a system that utilizes a knowledge graph, or cognitive engineering graph (CEG), for capturing a domain knowledge and associated rules in a semantic form, e.g. as an ontology. An ontology may be defined as a set of concepts and categories in a subject area or domain that shows their properties and the relations between them. An ontology may also be referred to as a structured model of an industry-specific domain. By using a knowledge graph, the domain knowledge, including the domain entities and relations, as well as rules for best practices, limits, tolerances, industry standards, etc., may be interlinked and connected in a visual representation. A certain domain-specific problem may then be modeled in the knowledge graph, or CEG, and defined as an instance based on the domain ontology or linked against the domain ontology. A reasoning module may then be used to reason the instance data with the domain's best practices and rules. The result of the reasoning may include violations of the domain's best practices, limits, tolerances, industry standards, etc. The results may be presented to a user as messages or annotations to the corresponding entities in the domain's model.

By using a knowledge graph to organize and connect domain-specific knowledge to a specific engineering environment, engineering support or assistance may be, at least in part, generated automatically, thereby formalizing and accelerating the engineering problem solving process. The domain ontology and representation of the ontology in the knowledge graph may be used in any variety of applications and is not limited to providing assistance for particular domains like the engineering approaches described above. For example, a domain ontology and representation of the ontology in the knowledge graph may be used in business process management applications to provide assistance with those systems. Because the domain knowledge is captured in a knowledge graph, transparency of the engineering process is increased because the knowledge graph may be reviewed more easily. The result is that engineering problem solving becomes faster, easier, and less prone to errors. Engineering projects developed in this way may be more efficient, reliable, and safe because errors in the engineering process are more easily avoided and detected. The proposed solution also ensures adherence to best practices specific to the environment being modeled. For example, the proposed solution allows products being manufactured in an automation engineering setting, such as car doors being made on a robotic assembly line, to be built according to best practices that are linked and available in the knowledge graph.

It is to be understood that elements and features of the various representative embodiments described below may be combined in different ways to produce new embodiments that likewise fall within the scope of the present teachings.

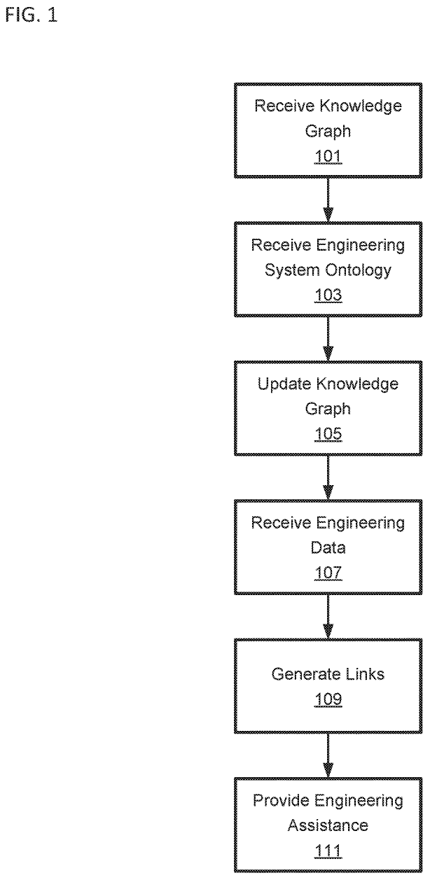

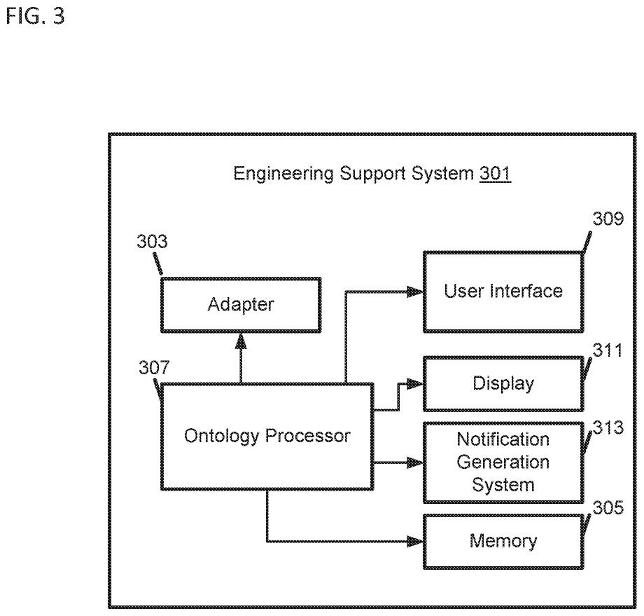

FIG. 1 illustrates a flowchart fora method of providing engineering assistance. The engineering assistance is provided based on domain knowledge captured in a knowledge graph. More, fewer, or different acts may be performed. In some cases, act 105 may be omitted. The acts may be performed in a different order than shown. For example, act 107 may follow act 109. A processor coupled to a memory may be configured to perform one or more of the acts. For example, the ontology processor 307 of FIG. 3 may be configured to perform one or more of the acts of FIG. 1.

In act 101, a knowledge graph is received. The knowledge graph is a structured representation of the world, or a part thereof. Nearly any kind of information, e.g. from internet searches to information about industrial and automation technologies or engineering principles may be represented in the knowledge graph. The knowledge graph may include information from a domain specific ontology, such as an engineering domain ontology. For instance, using the road curvature example above, the knowledge graph may contain at least a transportation engineering ontology. In this example, the knowledge graph may also contain an ontology related to state and federal highway regulations, which are pertinent to designing a roadway. The knowledge graph may be implemented in the form of a textual, graphical, or three-dimensional display, augmented reality, virtual reality interface, spreadsheet, linked files, or otherwise.

In some cases, the knowledge graph may be received or accessed by an adapter, such as the knowledge graph adapter 303 of FIG. 3. As stated above, the knowledge graph may include a domain specific ontology, such as an engineering domain ontology for an engineering domain. The domain ontology may also include a set of rules. As discussed above, the rules may consist of best practices, limits, tolerances, industry standards, etc. In some cases, the knowledge graph may not originally contain the domain ontology and the domain ontology may be incorporated into the knowledge graph. For example, the adapter 303 may modify or update the knowledge graph to include information from the domain ontology. Because knowledge graphs (and ontologies) may exist in different formats, standardized and proprietary, the adapter may be configured to translate the domain ontology as well as queries into the right target format for the knowledge graph. In this way, the knowledge graph may accept information from different graph databases and presented in different standards (e.g. triple/quad stores, property graphs, RDF/OWL/SPARQL, and/or tinker pop/gremlin).

In the knowledge graph, the domain ontology may be represented in semantic form. In semantic form, the nodes (e.g. entities) and structure of the domain ontology, such as relations, are represented in the knowledge graph by a semantic network, or web, of the knowledge graph. The semantic network expresses the relationships (e.g. including dependencies, flows, and hierarchies) between the nodes of the domain ontology. The domain ontology may contain information at different levels of generality or in a hierarchy. For example, the domain ontology may contain information about classes of entities and about specific entities. In this regard, the domain ontology is a structured model of the domain the ontology represents. For example, the engineering domain ontology is a structured model of the engineering domain. In another example, a healthcare domain ontology is a structured model of the healthcare domain.

The domain ontology, such as the engineering domain ontology, is data that represents a specific industry or domain, such as engineering. For example, the domain ontology may include information about an industry (e.g., engineering), a particular industrial facility (e.g., wastewater treatment plant), a particular industrial process within the facility (e.g., water filtration process), and/or a particular instance of the industrial process (e.g., UV light filtration). Some domain ontologies may include information at more than one level in the hierarchy. For example, the domain ontology may include information about both an industry in general and a particular instance of an industrial process. Other combinations are possible.

The domain ontology may initially be part of the knowledge graph or may be added. For example, the domain ontology may be manually or automatically added to the knowledge graph. The domain ontology may be expressed in the knowledge graph as an ontology defined by a semantic web of the knowledge graph. The semantic web may structure the information of the domain ontology and include information about hierarchies, dependencies, and information and material flows within the domain ontology.

The domain ontology may represent a part of the information contained in the knowledge graph and elements of the domain ontology may be linked to other information in the knowledge graph. For example, nodes, entities, or other elements of the domain ontology may be linked to information of other related ontologies.

In act 103, an engineering system ontology from one or more engineering systems is received. The engineering system ontology may be a set of related concepts and categories specific to an engineering system. The work of an engineer may be performed with engineering systems that support the engineer in his or her tasks. The engineering systems may include mechanical systems, electrical systems, programming systems, simulation systems, or any combinations of these or other similar engineering systems. An example of a mechanical system is Computer-Aided Design and Manufacture (CAD/CAM) software. An example of an electrical system is Electronic Computer-Aided Design (ECAD) software. An example programming system is a Programmable Logic Controller (PLC) automation software. Example simulation systems are Finite Element Method (FEM) software, Electronics simulation software, and Fluid simulation software. Each of these systems may have its data represented in the knowledge graph. For example, each system may connect to the knowledge graph and represent its data as it is structured internally in an ontology. In some cases, an engineering system may also be a runtime system that collects actual live data from a field device, like a machine or sensor. An example of field device that captures live data for engineering purposes is a remote-controlled sewer pipe inspection unit that collects, for example, sonar, GPS, and laser data in order to evaluate sewer pipe structural defects (i.e., cracks) and corrosion build up.

The engineering system ontology includes information about a specific engineering system. By including both the domain ontology and the engineering system ontology in the knowledge graph, engineering assistance may be provided based on the engineering system ontology using information in the domain ontology. For example, links, or data associations, in the knowledge graph may connect the engineering system ontology and the domain ontology in the knowledge graph. The engineering system ontology may include properties or specifications of the engineering system. The properties may include a role of the engineering system in the engineering domain or a relationship between the engineering system and the engineering domain.

In act 105, the knowledge graph is updated to include the engineering system ontology. Alternatively, this act may be omitted since in some cases, the knowledge graph may already contain the engineering system ontology. In some cases, the adapter, such as the knowledge graph adapter 303 of FIG. 3, or a processor, such as the ontology processor 307 of FIG. 3, may be configured to update the knowledge graph. The knowledge graph may be updated to include the properties of the one or more engineering systems as well. For example, the knowledge graph may be updated to include the engineering system ontology, the role of the one or more engineering systems in the engineering domain, and/or the relationship between the one or more engineering systems and the engineering domain. The roles and relationships (and other entities of the engineering systems properties or engineering system ontology) may be semantically represented in the knowledge graph. In this way, once updated, the knowledge graph may include information about the domain ontology and the engineering system ontology, which may be linked together.

The knowledge graph adapter may be configured to transform other information into the proper format for use in the knowledge graph. Additionally or alternatively, the knowledge graph adapter may be configured to modify the knowledge graph. For example, the adapter may receive instructions from one of the one or more engineering systems (e.g. contained in the engineering system ontology or in another form) to add, remove, modify, update, or manipulate knowledge graph data. The adapter may be configured to transform the domain ontology and/or the engineering system ontology into a proper format for inclusion in the knowledge graph. The adapter may update the knowledge graph to include information in the domain ontology and/or the engineering system ontology. In some cases, the adapter may be configured to query the knowledge graph. For example, the engineering system may send a query that is received by the adapter. The adapter may execute the query on the knowledge graph and return information to the engineering system based on the query. These queries may be performed automatically by the engineering system or by a user of the engineering system.

The engineering system may receive user input via an input device, such as the user interface 309 of FIG. 3. The engineering system properties or engineering system ontology may be changed, selected, identified, or defined based on user input or predefined rules.

The engineering system ontology from the one or more engineering systems may not completely align with the representation of the industry domain knowledge (i.e., the information in the engineering domain ontology). However, the engineering domain knowledge may be interpreted correctly in the context of the engineering domain when additional semantic links are established, for example about the role of the engineering systems and the engineering systems' relations in the engineering domain. A linking component may create this additional semantic linking by creating data associations between the two ontologies. A semantic link is a link that conforms to semantics of an ontology and makes sense based on the text used in the ontology and the industry of the ontology.

In act 107, engineering data from a first engineering system of the one or more engineering systems is received. The engineering data may be received by an adapter, such as the knowledge graph adapter 303 of FIG. 3, or a processor, such as the ontology processor 307 of FIG. 3. The engineering data, or instance data, may include one or more specifications of an engineering project, a proposed engineering design, a specific engineering problem, or any combinations thereof. The engineering data may include other kinds of data as well. For example, the engineering data may also include data pertaining to the engineering system from which it originated, such as the default values for particular engineering system specifications. In one example, an engineering system related to bridge design may include a default value for bridge load rating. The bridge load rating may be a type of engineering data that is received by the adapter or ontology processor. Once the domain specific ontology is semantically linked to the engineering system specific ontology, any instance data that an engineering system provides may be interpreted as domain specific instance data. The domain specific instance data, or engineering data, may be presented to the user of the engineering system to provide context about the objects he or she is engineering with the engineering system in relation to the linked domain ontology and other engineering systems.

In act 109, one or more links, or data associations, in the knowledge graph are generated. Alternatively, this act may be omitted since in some cases, the knowledge graph may already contain the links, or data associations between the various components of the knowledge graph. In some cases, this act may precede act 107. The links may be generated by a processor, such as the ontology processor 307 of FIG. 3. The links may be generated between the domain ontology, the engineering system ontology, and the engineering data. For example, a link may connect a property of an engineering system, such as a role of the engineering system in the engineering domain, to data in the domain ontology. In another example, a link may connect one or more specifications of an engineering project, a proposed engineering design, or a specific engineering problem to a property of an engineering system or to data in the domain ontology. The links may be based on the one or more engineering systems, the engineering domain, the engineering data, and the engineering domain ontology.

Generating the one or more links, or data associations, may be performed by analyzing the engineering domain ontology and the engineering system ontology for each of the one or more engineering systems and providing semantic links between the engineering domain ontology and the engineering system ontologies. In one embodiment, this analysis may be performed manually. For example, a human expert may be presented with the domain ontology and an engineering system ontology side by side and then the human expert may manually provide the actual semantic linking or associations between the two ontologies. In another embodiment, the linking is performed automatically by a machine learning algorithm that investigates a large number of existing linked domain ontologies and engineering system specific ontologies in order to predict and propose links for the additional engineering systems ontology that is to be linked. For example, generating the one or more links may be performed automatically by a machine-learned network, such as, for example, a deep neural network. The machine-learned network may be trained to generate links using training data with existing links between the engineering domain ontology and one or more engineering system specific ontologies.

Providing links, or data associations, between various engineering system ontologies from different engineering systems, and between the domain ontology and the different engineering systems, allows users of engineering systems to navigate and explore, through the domain specific ontologies, the data of other engineering systems that are represented in the knowledge graph. This is very valuable in today's engineering world that often includes tens of engineering systems that are typically not connected. For example, one engineering system, such as a mechanical system (CAD), may be linked to another engineering system, such as a simulation, or modeling, system. In another example, service and maintenance systems may be linked and available to a user. This linking allows various related systems to communicate and share information with each other in an improved manner that facilitates faster and more efficient problem solving. Information not typically available to a user of an engineering system, such as an inexperienced engineer or an engineer specializing in a narrow field, is now available through the knowledge graph.

Links may be provided to other systems or resources other than specific engineering systems. Any system or model related to the domain may be linked in the knowledge graph. For example, for a manufacturing domain, the manufacturing domain ontology may be linked to a Product Lifecycle Model (PLM), a government regulation ontology that governs the item being manufactured, and a mechanical engineering system ontology. Other systems that may be potentially linked in the knowledge graph include Enterprise Resource Planning (ERP) systems, Manufacturing Execution Systems (MES), runtime-operating systems, driver systems, and mobile device application systems.

Links may be established in a number of ways. For example, inference and reasoning using a reasoner, for example an OWL-reasoner, may be used to generate links. For example, the reasoner may deduce that a train brake is frictionless when it is indicated that the train brake is an electromagnetic brake and the ontology for the braking domain defines that electromagnetic brakes are frictionless.

Links may also be generated using prediction through an artificial intelligence component, such as a deep learning neural network that may be trained by using a large amount of historical project data. For example, predicting that a train control module has a safety operation mode may be possible because most historic projects with a train control module indicate a safety operation mode.

In another example, links may be generated using domain specific algorithms. For example, an algorithm incorporating the process of identifying equivalent objects in a mechanical- and an electrical-engineering system may be used to establish links between the electrical and mechanical representations of a train brake.

Links may also be created by using domain specific update queries. An update query is defined as a regular graph query, but with an instruction for adding or removing additional facts or links to/from a knowledge graph. An example query language that allows update queries is the SPARQL language. This makes it possible to query a subgraph and use the result for further processing. For example, a query for all ontology classes that have a property for “operating temperature limit” allows a link to be added to the class “temperature controlled” for all results found.

Additionally, links may be generated or added manually through a domain expert. In this case, the domain expert may review the collected knowledge and add additional facts and links to the knowledge graph. For example, the domain expert for the train brakes may establish two links by defining that a simulation result of a brake belongs to the train brake representation in the ERP system and that the simulation result is conforming to the industry standard for train brake ratings.

In act 111, engineering assistance for the first engineering system is provided. The engineering assistance may be provided based on the knowledge graph, the one or more generated links, the engineering data, and the engineering domain. In one embodiment, providing the engineering assistance includes providing data from the engineering domain ontology associated with the engineering data of the first engineering system, based on the generated one or more links, to a user of the first engineering system. In another embodiment, providing the engineering assistance includes providing data from the engineering domain ontology associated with an engineering system ontology from a second engineering system. In this regard, a user of one engineering system has access to knowledge of another, related engineering system to which the user may not normally have access.

For example, in a traditional engineering firm, there may be groups of engineers that each specialize in a different field of engineering. Even within the same discipline of engineering, such as civil engineering, different engineers may focus on different sub-specialties. For example, within a group of engineers that focus on transportation engineering, one engineer may specialize in bridge designs (structural engineer), another engineer may specialize in hydraulics (water resources engineer), and another engineer may specialize in soil-water interactions (geotechnical engineer). While all of these engineers may be working together to design a roadway, traditionally each engineer focuses on their individual part and interacts with the other engineers only when their specialties overlap. For example, if the structural engineer encounters an issue with their bridge design that involves water flow, the structural engineer may need to involve the water resources engineer to help solve that particular problem. Similarly, if the problem also involves soil-water interaction, both the structural engineer and the water resources engineer may need to involve the geotechnical engineer.

With the knowledge graph including the domain ontology and multiple engineering system ontologies, the knowledge graph may link engineering system ontologies from the structural, water resources, and geotechnical engineering systems. This allows the user of the structural engineering system (the structural engineer in the example above) to navigate and explore, through the domain specific ontologies for the other disciplines, the data of other engineering systems, such as the water resources engineering system and the geotechnical engineering system, that are represented in the knowledge graph. In this example, the structural engineer may be able to solve his particular problem and complete his portion of the roadway design without having to involve the water resources engineer or the geotechnical engineer.

In one embodiment, providing engineering assistance, or support, may first include analyzing the engineering data, the set of rules of the engineering domain ontology, and the associated data from the engineering domain ontology. The analysis may be based on the generated one or more links. Next, input may be provided to a user of the first engineering system. The input may be based on the analysis of the engineering data, the set of rules of the engineering domain ontology, and the associated data from the engineering domain ontology.

In this example, the analysis may involve comparing the engineering data and the set of rules of the engineering domain ontology and determining whether the engineering data complies with the set of rules of the engineering domain ontology. For example, the set of rules may involve industry standards for a particular design. In this case, the engineering data, such as specifications of an engineering project or a proposed engineering design, may be compared to the industry standards to determine whether the specifications or proposed design complies with the industry standards. The results of this analysis are provided to the user of the engineering system as input. This provides engineering assistance, or support, to the user. For example, knowing whether particular specifications of an engineering project or a proposed engineering design complies with industry standards is valuable input to a user of an engineering system.

The analysis described above may be performed by an automated reasoner. The automated reasoner may be part of the ontology processor. Alternatively, the automated reasoner may be a separate unit of the engineering support system. The automated reasoner may reason over the engineering systems data using the domains knowledge and best practices. The reasoning results may be inferences but also inconsistencies, problems or warnings.

The reasoning results may be fed back to the knowledge graph and serve as annotations to the knowledge graph nodes. Additionally, the reasoning results may be presented to a dedicated messaging service, or engineering system integrations, that ensures critical issues are brought to the attention of engineers and managers immediately. The messaging service may be configured by domains and areas of responsibility in terms of knowledge graph connected systems. This allows targeting the right personnel with messages. The messages may be constructed with the relevant excerpts from the knowledge graph for inspection and contain links to the knowledge graph for immediate exploration capability.

In one embodiment, providing the input discussed above may include generating and providing a message to the user of the first engineering system based on the analysis of the engineering data, the set of rules of the engineering domain ontology, and the associated data from the engineering domain ontology. As discussed above, the message may include an annotation in the knowledge graph or a communication through a messaging service or engineering system integrations.

The proposed solution may be integrated into an engineering system, such that as soon as a user inputs data into an engineering system (i.e., engineering data), that data is automatically provided to the adapter or ontology processor, which analyzes the data in context with the domain ontology and the engineering system ontology, and provides input based on that analysis in the form or annotations to the knowledge graph or as messages that indicate inferences, inconsistencies, problems and/or warnings.

Receiving this sort of reasoned input, or engineering assistance or support, allows for designing or redesigning the engineering project, the proposed engineering design, or a solution to the specific engineering problem associated with the engineering data. The designing or redesigning may be performed by the processor or the user of the engineering system.

There are many examples for how this type of automated reasoning is beneficial in a domain. In one example, the domain for automotive manufacturing has safety standards for how to secure a robot cell with fences that keep humans out of reach of the active robot. A mechanical engineering system has modeled the robot cell as 3D objects and through the linked domain information it can be inferred that a certain 3D object is the fence and another 3D object is the robot. A semantic rule contained in the domain ontology has also been defined that the fence has to be out of the robot's range, but the position of the fence together with the connected robot reach attribute (i.e., engineering data from the engineering system) indicate that the domain safety standard is violated. This prompts a valuable message to the engineer who can now position the fence differently and avoid the potential danger to human workers and costly lawsuits.

In another example, in the industry of train manufacturing it may be required to have approved braking profiles that are proven by accompanied simulation data. In one specific instance of a project, the train engineering has been completed but the braking simulation was performed with a resulting parameter out of the target range. This small oversight may be detected by a reasoner that compares the inferred simulation instances parameters to the must have ranges, or tolerances, in the domain specified parameters. The engineer is notified with a message and a costly delay can be avoided.

In another example alluded to above, an engineering system related to bridge design may include a default value for bridge load rating. The bridge load rating may be a type of engineering data that is received by the adapter or ontology processor. As discussed above, as soon as the engineering system is linked to the engineering domain ontology, the automated reasoner may compare the engineering data and the set of rules of the engineering domain ontology and determine whether the engineering data complies with the set of rules of the engineering domain ontology. If the bridge load rating value for the engineering system is not in compliance, the engineer is notified immediately before substantial design work is completed, which may save design time and money.

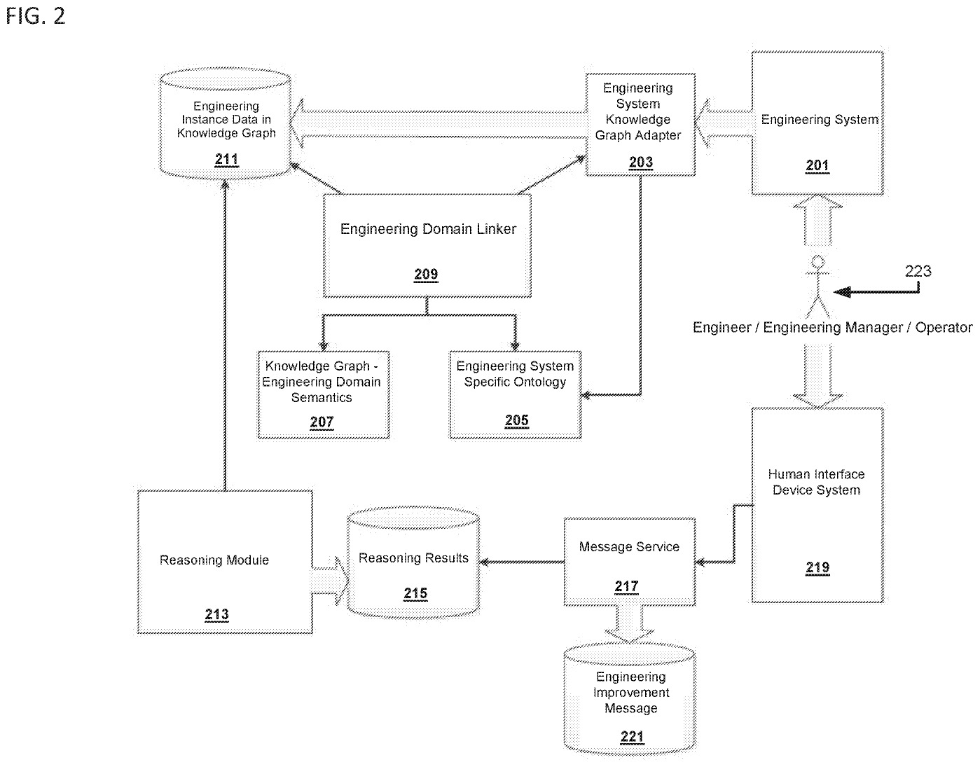

FIG. 2 illustrates a flowchart for providing engineering support from domain knowledge captured in a knowledge graph including an engineering domain ontology 207 and an engineering system specific ontology 205.

As shown in FIG. 2, a user 223, such as an engineer, engineering manager, or operator, is using an engineering system 201. The engineering system 201 is connected to an engineering system knowledge graph adapter 203, which may be the same as the adapter discussed above or as the knowledge graph adapter 303 of FIG. 3. The adapter 203 receives an engineering system specific ontology 205 from the engineering system 201.

The engineering domain linker 209 generates the links discussed above with respect to FIG. 1, such as links to the adapter 203, the engineering system specific ontology 205, the knowledge graph including an engineering domain ontology 207, and engineering instance data 211. The linker 209 may be part of the ontology processor, such as the ontology processor 307 of FIG. 3, or as a separate module. For example, the engineering domain linker 209 may create semantic linking by creating data associations between the engineering system specific ontology 205, the knowledge graph including an engineering domain ontology 207, and engineering instance data 211. These semantic links are links that conform to semantics of each ontology and makes sense based on the text used in the ontologies and the industry of the ontology, or the domain, such as the engineering domain in the case of FIG. 2.

The reasoning module 213 analyzes the engineering instance data 211, the data of the engineering domain ontology 207, which may contain a set of rules, such as best practices, limits, industry standards, and tolerances, and the associated data from the engineering system specific ontology 205. The analysis may be based on the generated one or more links created by the engineering domain linker 209. The reasoning module 213 may be part of the ontology processor, such as the ontology processor 307 of FIG. 3, or as a separate module.

The reasoning module 213 determines reasoning results 215, which may be stored in a memory, such as memory 305 of FIG. 3. The reasoning results 215 may be provided to the user 223 of the engineering system 201 as message in the form of an annotation to the knowledge graph 207 or as a communication through a messaging service, such as message service 217, or engineering system integrations. The message service 217 may be part of the notification generation system 313 of FIG. 3.

As shown in FIG. 2, the message service 217 accesses the reasoning results 215 and provides engineering improvement messages 221 based thereon. The user 223 may access the messages 221 from the message service 217 through a human interface device system 219. The human interface device system 219 may be the user interface 309 of FIG. 3. The interface 219 may allow for browsing, editing, and querying of the knowledge graph containing engineering domain semantics 207, the engineering system specific ontology 205, the engineering instance data 211, as well as the reasoning results 215 and engineering improvement messages 221, thereby enabling users 223 of the engineering system 201 to inspect, understand, and audit each of these components. Using the interface 219, users 223 may input commands creating or modifying entities in the knowledge graph, establishing links between the entities in the knowledge graph, and creating instances of the knowledge graph. Because the interface 219 works with the knowledge graph, users 223 of any engineering system may benefit from the transparency, reliability, and other benefits of providing engineering assistance or support, such as engineering improvement messages 221, based on the knowledge graph.

In some cases, the interface 219 may be provided by the engineering system 201. In some other cases, the interface 219 may be implemented by one or more components of the engineering support system, for example, user interface 309, the display 311 and adapter 303 of FIG. 3.

FIG. 3 is a block diagram of one embodiment of a system for providing engineering support using a knowledge graph. The engineering support system 301 may include an ontology processor 307 coupled with a memory 305 and in communication with an adapter 303, a user interface 309, a display 311, and a notification generation system 313. The engineering support system 301 may also be in communication with a server (not shown).

The engineering support system 301, including one or more components 303-313 of the engineering support system 301, may be configured to perform one or more of the acts of FIG. 1 or other acts. The engineering support system 301 may be implemented in one or many different forms. For example, the engineering support system 301 may be implemented as a desktop computer program, a server-based computer program, a mobile application, a cloud-based service, or otherwise. The engineering support system 301 may be general and not specific to an industry or domain. This is achieved by a method of domain integration by linking to data in the knowledge graph that represents a specific industry or domain (e.g. FIG. 1).

The ontology processor 307 may be a general purpose or application specific processor. The ontology processor 307 may be configured to or may execute instructions that cause the ontology processor 307 to generate one or more links in the knowledge graph between the domain ontology and the engineering system ontology based on the one or more engineering systems, the engineering domain, and the domain ontology. The ontology processor 307 may also be configured to provide engineering assistance for the first engineering system based on the knowledge graph, the one or more links, the engineering data, and the engineering domain. In some cases, the ontology processor 307 may be configured to receive a knowledge graph including a first structured model of an industry-specific domain, such as an engineering domain ontology for an engineering domain. The ontology processor 307 may interface with the knowledge graph through the adapter 303. The ontology processor 307 may access, send, or receive data from the knowledge graph through the adapter 303. For example, the ontology processor 307 may receive a second structured model of an industry-specific system, such as an engineering system ontology from one or more engineering systems, through the adapter. Additionally or alternatively, the ontology processor 307 may interface with the knowledge graph directly or through another intermediary. The ontology processor 307 may also be configured to receive data, from a first industry-specific system, such as engineering data from a first engineering system.

The memory 305 may be a non-transitory computer readable storage medium. The memory 305 may be configured to store instructions that cause the processor to perform an operation. For example, the memory 305 may store instructions that, when executed by the processor 307, cause the processor 307 to perform one or more acts of FIG. 1 or other acts. The memory 305 may be configured to store a domain ontology, an engineering system ontology, a knowledge graph, engineering data from engineering systems, reasoning results, engineering improvement messages or notifications, or other information. The instructions for implementing the processes, methods, and/or techniques discussed herein are provided on non-transitory computer-readable storage media or memories, such as a cache, buffer, RAM, removable media, hard drive, or other computer readable storage media. Non-transitory computer readable storage media include various types of volatile and nonvolatile storage media.

The adapter 303 may be a software module executed by the ontology processor 307. In some cases, the adapter 303 may be implemented by a separate processor or by standalone hardware. Though a single adapter 303 is shown, multiple adapters 303 may be present.

The adapter 303 may be configured to receive a domain ontology and translate the domain ontology into a knowledge graph. Additionally or alternatively, the adapter 303 may be configured to receive an engineering system ontology from one or more engineering systems and update or modify the knowledge graph to include an engineering system ontology. The adapter 303 may also be configured to receive engineering data from a first engineering system of the one or more engineering systems.

Additionally or alternatively, the adapter 303 may be configured to query the knowledge graph. For example, the engineering system may send a query that is received by the adapter 303. The adapter 303 may execute the query on the knowledge graph and return information to the engineering system based on the query. Additionally or alternatively, the adapter 303 may be configured to modify the knowledge graph based on the query. For example, a user may provide input (e.g. through the user interface 309 or the display 311) containing instructions to create or modify entities or links in the knowledge graph and the adapter 303 may be configured to carry out the instructions. The query results may be displayed to the user through the display 311.

The user interface 309 may be configured to provide user input, such as to input instructions to create or modify entities or links in the knowledge graph. The user interface 309 may be the human interface device system 219 of FIG. 2. The user interface 309 may include an input device such as a keyboard, mouse, display, touchscreen, or other human interface device and an output device, such as the display 311. A user may change, select, identify, or define the specifications or ontology of the engineering system via the user interface 309. For example, a user may use the user interface 309 to generate an input to the engineering system identifying properties or other specifications of the engineering system or the engineering system ontology. In some cases, the user may input a query to the engineering system using the user interface 309. The query may be executed by the adapter 303.

The display 311 may be configured to accept user input and to display audiovisual information to the user. In some cases, the display 311 may include a screen configured to present the audiovisual information. For example, the display 311 may present the knowledge graph. The interface 219 of FIG. 2 may be implemented by the processor 307 using the display 311. Via the display 311, users of the interface 219 may inspect the knowledge graph and check the entities and links as well as the engineering data 211, the reasoning results 215, and the engineering improvement messages 221. The display 311 may include a user input device. For example, the display may include a keyboard, mouse, and/or a virtual or augmented reality environment. In some cases, the user may input information relating to defining new or additional engineering data or for modifying the knowledge graph. In some cases, the user interface 309 may be part of the display 311.

The notification generation system 313 may be part of the ontology processor 307. Alternatively, the notification generation system 313 may be a separate unit of the engineering support system 301 and may include its own processor and memory. The notification generation system 313 may be configured to provide input to the user of an engineering system based on the analysis of the engineering data, the set of rules of the engineering domain ontology, and the associated data from the engineering domain ontology based on the generated links. In some cases, the notification generation system 313 may be configured to provide input to the user based on the analysis performed by the reasoning module 213 of FIG. 2. The notification generation system 313 may be configured to generate and provide messages to users of engineering systems. As stated above, the messages may be an annotation in the knowledge graph or a communication through a messaging service or engineering system integrations. In this case, the notification generation system 313 may be configured to feed the reasoning results 215 back to the knowledge graph in the form of annotations to the graph nodes of the knowledge graph. The notification generation system 313 may also be configured to present the reasoning results 215 to a dedicated messaging service, such as the message service 217 of FIG. 2, to ensure that critical issues are brought to the attention of users 223 of the engineering system 201, such as engineers, managers, and operators.

The notification generation system 313 may be configured according to specific domains and/or areas of user responsibility in terms of knowledge graph connected systems. This allows the notification generation system 313 to generate messages that target the right personnel with appropriate messages. The notification generation system 313 may be configured to generate messages with relevant excerpts from the knowledge graph for inspection. The notification generation system 313 may also be configured to generate messages with links to the knowledge graph for immediate exploration capability.

In an alternative embodiment, the engineering support system 301 may be connected to a server via a network. In this example, the server may provide, or store in a local memory, the knowledge graph including a first structured model of an industry-specific domain, such as an engineering domain ontology for an engineering domain. In this example, the ontology processor 307 or the adapter 303 of the engineering support system 301 may be configured to generate and send to the server the engineering system ontology from the one or more engineering systems. In this example, the ontology processor 307 or the adapter 303 of the engineering support system 301 may be configured to generate the links in the knowledge graph. Alternatively, the server may be configured to generate the data associations in the knowledge graph. In this example, the engineering support system 301 may be configured to provide the engineering support as discussed above. Alternatively, the server may be configured to provide the engineering support by communication with the notification generation system 313 or with a dedicated messaging service, such as the message service 217 of FIG. 2.

The embodiments disclosed above improve the engineering process by allowing for the introduction of explicit knowledge graph models for best practices in a specific industry domain. The disclosed embodiments provide a support system that reasons over instance data using the linked ontologies for best practices and provides the results to a messaging system. The disclosed system is able to link the domain knowledge representation to engineering system specific knowledge representation (both automatic and manual), which allows for greater access between different engineering systems that traditionally are not linked together. The proposed embodiments also provide a system for message storage and presentation that allows messages to be both represented in the knowledge graph and sent directly to a user.

While the invention has been described above by reference to various embodiments, it should be understood that many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention.

I (we) claim:

1. A method for providing engineering assistance, the method comprising:
receiving, by a processor, a knowledge graph including an engineering domain ontology for an engineering domain, the engineering domain ontology including a set of rules;
receiving, by the processor, an engineering system ontology from one or more engineering systems;
updating, by the processor, the knowledge graph to include the engineering system ontology;
receiving, by the processor, engineering data from a first engineering system of the one or more engineering systems, wherein the engineering data includes one or more specifications of an engineering project, a proposed engineering design, a specific engineering problem, or combinations thereof;
generating, by the processor, one or more links in the knowledge graph between the engineering domain ontology, the engineering system ontology, and the engineering data based on the one or more engineering systems, the engineering domain, and the engineering domain ontology; and
providing, by the processor, engineering assistance for the first engineering system based on the knowledge graph, the one or more links, the engineering data, and the engineering domain.

2. The method of claim 1, wherein the engineering domain ontology is represented in semantic form in the knowledge graph, and
wherein one or more nodes or relations of the engineering domain ontology are represented in the knowledge graph as an ontology defined by a semantic network of the knowledge graph.

3. The method of claim 1, wherein the one or more engineering systems include a mechanical system, an electrical system, a programming system, a simulation system, or combinations thereof.

4. The method of claim 1, wherein generating the one or more links is based on a property of the one or more engineering systems, wherein the property includes a role of the one or more engineering systems in the engineering domain or a relationship between the one or more engineering systems and the engineering domain.

5. The method of claim 1, wherein generating the one or more links is performed by analyzing the engineering domain ontology and the engineering system ontology and providing semantic links between the engineering domain ontology and the engineering system ontology.

6. The method of claim 1, wherein generating the one or more links is performed automatically by a machine-learned network, the machine-learned network having been trained with existing links between the engineering domain ontology and one or more engineering system specific ontologies.

7. The method of claim 1, wherein providing the engineering assistance comprises providing data from the engineering domain ontology associated with the engineering data of the first engineering system, based on the generated one or more links, to a user of the first engineering system.

8. The method of claim 1, wherein providing the engineering assistance comprises providing data from the engineering domain ontology associated with an engineering system ontology from a second engineering system.

9. The method of claim 7, wherein providing the engineering assistance further comprises:
analyzing the engineering data, the set of rules of the engineering domain ontology, and the associated data from the engineering domain ontology based on the generated one or more links; and
providing input to the user of the first engineering system based on the analysis.

10. The method of claim 9, wherein analyzing comprises:
comparing the engineering data and the set of rules of the engineering domain ontology; and
determining whether the engineering data complies with the set of rules of the engineering domain ontology.

11. The method of claim 9, wherein providing input comprises generating and providing a message to the user of the first engineering system based on the analysis, wherein the message comprises an annotation in the knowledge graph or a communication through a messaging service or engineering system integration.

12. The method of claim 1, further comprising designing or redesigning, by a processor of the first engineering system, the engineering project, the proposed engineering design, or a solution to the specific engineering problem associated with the engineering data, wherein the first engineering system includes a mechanical system, an electrical system, a programming system, a simulation system, or combinations thereof.

13. A system for providing engineering assistance, the system comprising:
an adapter configured to receive a domain ontology for an engineering domain, translate the domain ontology into a knowledge graph, receive an engineering system ontology from one or more engineering systems, update the knowledge graph to include the engineering system ontology, and receive engineering data from a first engineering system of the one or more engineering systems, wherein the engineering data includes one or more specifications of an engineering project, a proposed engineering design, a specific engineering problem, or combinations thereof; and
an ontology processor configured to generate one or more links in the knowledge graph between the domain ontology, the engineering system ontology, and the engineering data based on the one or more engineering systems, the engineering domain, and the domain ontology, and provide engineering assistance for the first engineering system based on the knowledge graph, the one or more links, the engineering data, and the engineering domain.

14. The system of claim 13, wherein the ontology processor is configured to generate, by a machine-learned network, the one or more links by analyzing the domain ontology and the engineering system ontology and providing semantic links between the domain ontology and the engineering system ontology, wherein the machine-learned network is trained with existing links between the domain ontology and one or more engineering system specific ontologies.

15. The system of claim 13, wherein the ontology processor is configured to provide the engineering assistance by providing data from the domain ontology associated with the engineering data of the first engineering system, based on the generated one or more links, to a user of the first engineering system.

16. The system of claim 15, wherein the domain ontology includes a set of rules, and the ontology processor, to provide the engineering assistance, is further configured to:
analyze the engineering data, the set of rules of the domain ontology, and the associated data from the domain ontology based on the generated one or more links; and
provide input to the user of the first engineering system based on the analysis.

17. The system of claim 16, wherein the ontology processor is further configured to analyze the engineering data by:
comparing the engineering data and the set of rules of the domain ontology; and
determining whether the engineering data complies with the set of rules of the domain ontology.

18. The system of claim 16, wherein the ontology processor is further configured to provide input by generating and providing a message to the user of the first engineering system based on the analysis, wherein the message comprises an annotation in the knowledge graph or a communication through a messaging service.

19. An industry-specific support notification system comprising:
an ontology processor, coupled with a memory containing instructions that, when executed, cause the ontology processor to:
receive a knowledge graph including a first structured model of an industry-specific domain, the first structured model including a set of rules for the industry-specific domain;
receive a second structured model of an industry-specific system from one or more industry-specific systems;
generate one or more data associations between the first structured model and the second structured model based on the one or more industry-specific systems, the industry-specific domain, and the first structured model;
receive data from a first industry-specific system of the one or more industry-specific systems; and
provide an industry-specific support notification for the first industry-specific system based on the received data, the knowledge graph, the one or more data associations, and the industry-specific domain.

20. The system of claim 19, wherein the industry-specific support notification comprises an annotation in the knowledge graph or a communication through a messaging service or engineering system integration.
